(19) United States
(12) Patent Application Publication
(10) Pub. No.: US 2017/0062075 A1
(43) Pub. Date: Mar. 2, 2017

(54) APPARATUS INCLUDING CORE AND CLOCK GATING CIRCUIT AND METHOD OF OPERATING SAME

(71) Applicant: SANDISK TECHNOLOGIES INC., PLANO, TX (US)

(72) Inventors: EDGAR BARBER, NESS ZIONA (IL); RONEN GOLAN, PETAH-TIKVA (IL); ELI ELMOALEM, NILI (IL)

(73) Assignee: SANDISK TECHNOLOGIES INC.

(21) Appl. No.: 14/840,943

(22) Filed: Aug. 31, 2015

(51) Int. Cl. G11C 29/12; G06F 1/04; G06F 13/40

(52) U.S. Cl. CPC G11C 29/12015; G06F 13/4068; G06F 1/04

(57) ABSTRACT

A device may include a first core, a master clock core, and a clock gating circuit. The master clock core may generate a master clock signal. The clock gating circuit may clock gate the master clock signal in response to a stall signal from the first core.

### FIELD OF THE DISCLOSURE

The present disclosure is generally related to electronic devices and more particularly to test processes for electronic devices, such as during a test process for a data storage device.

### BACKGROUND

Storage devices enable users to store and retrieve data. Examples of storage devices include volatile memory devices and non-volatile memory devices.

Storage devices and other electronic devices may be tested after fabrication to verify device operation. For example, a device may be tested using a validation process to verify operation of the device. During testing, the device may be operated at a test facility using a variety of operating conditions so that software or hardware errors of the device may be detected. For example, if operation of the device deviates from a design specification of the device, then an error (or a “failure”) may be detected.

In order to debug the device, the error may be reproduced by a design facility (or developer) of the device so that a design of the device may be modified to remove the error. For example, the error may be reported by the test facility to the design facility, and the design facility may attempt to reproduce the error using a simulation or design tool, such as an electronic design automation (EDA) tool. Reproducing errors may be time consuming and may increase design, fabrication, and verification cost of a device. Further, in some cases, the designer may be unable to reproduce an error and may request the test facility to retest the device, which also increases cost.

### BRIEF DESCRIPTION OF THE DRAWINGS

FIG. 1 is a diagram of a particular illustrative example of a system that includes a device, such as a data storage device.

FIG. 2 is a diagram of a particular illustrative example of certain components that may be included in the device of FIG. 1.

FIG. 3 is a diagram of a particular illustrative example of a method of operation of the device of FIG. 1.

### DETAILED DESCRIPTION

A device may include a first core, such as a core of a central processing unit (CPU). The first core may include an action point detector that detects an action point during instruction execution by the first core (e.g., during a test process). For example, the action point detector may monitor a program counter of the first core to determine whether the first core accesses a particular address or range of addresses. If the first core accesses the particular address or range of addresses, the action point detector may detect an action point (i.e., the action point detector may detect that a particular condition has been satisfied, such as the first core accessing the particular address or range of addresses).

In response to detecting the action point, the action point detector may output a stall signal to one or more other components of the device. For example, the action point detector may provide the stall signal to a clock gating circuit using a system bus of the device. The clock gating circuit may clock gate a master clock signal of the device, such as by causing a master clock core of the device to cease to provide the master clock signal to certain device components (e.g., the first core and a second core of the device). In this example, clock gating the master clock signal may “preserve” (or “freeze”) states of the first core and the second core by halting instruction execution at the first core and the second core. Freezing the states may avoid modification of states of the cores (e.g., by preventing certain values stored by the cores from being overwritten or modified by one or more instructions executed after detection of the action point).

Halting execution at the cores in response to the stall signal may improve accuracy and/or efficiency of a debugging process. For example, halting the cores may enable a testing device to detect states of the cores when the action point is detected, which may improve accuracy and/or efficiency of debugging operations as compared to attempting to recreate (or “reverse engineer”) a failure using subsequent states (e.g., after values of the cores have been overwritten or modified during instruction execution). In some cases, the states may be used to debug the device “on site” in “real time” using information related to the failure (e.g., at a testing facility following occurrence of the failure), which may reduce cost as compared to reporting the error to another facility (e.g., a design facility) to attempt to reproduce the error.

Particular aspects of the disclosure are described below with reference to the drawings. In the description, common or similar features may be designated by common reference numbers. As used herein, “exemplary” may indicate an example, an implementation, and/or an aspect, and should not be construed as indicating a preference or a preferred implementation.

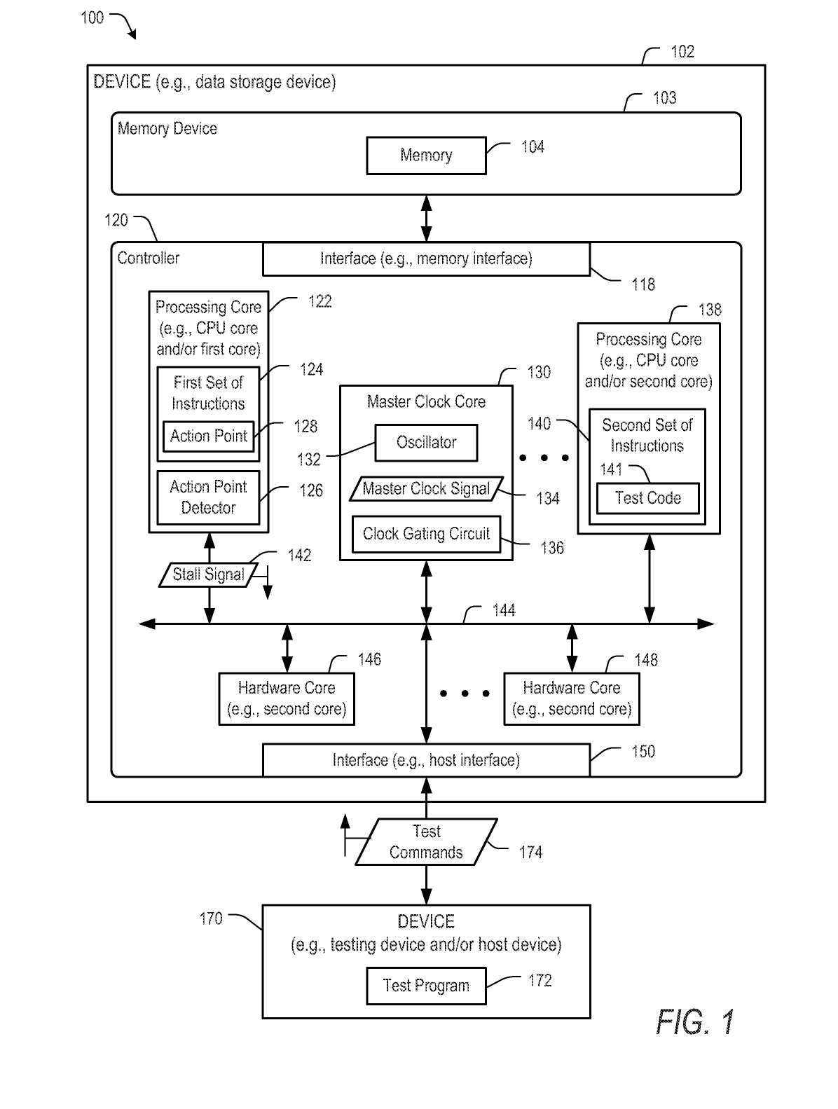

Referring to FIG. 1, a particular illustrative example of a system is depicted and generally designated 100. The system 100 includes a device 102 and a device 170 (e.g., a testing device, a host device, or an access device). In some implementations, the device 102 corresponds to a data storage device, such as a solid state drive (SSD) data storage device that is configured to be embedded within a device (e.g., the device 170) or a removable flash memory data storage device that is configured to be removed from a device (e.g., the device 170). In other implementations, the device 102 corresponds to another device, such as an application-specific integrated circuit (ASIC) or a system-on-chip (SoC) device, as illustrative examples.

The device 102 may include a memory device 103. The memory device 103 may include one or more memory dies (e.g., one memory die, two memory dies, sixty-four memory dies, or another number of memory dies).

The memory device 103 includes a memory 104, such as a non-volatile array of storage elements included in a memory die. The memory 104 may include a flash memory (e.g., a NAND flash memory) or a resistive memory, such as a resistive random access memory (ReRAM), as illustrative examples. The memory 104 may have a three-dimensional (3D) memory configuration. As used herein, a 3D memory device may include multiple physical levels of storage elements (instead of having a single physical level of storage elements, as in a planar memory device). As an example, the memory 104 may have a 3D vertical bit line (VBL) configuration. In a particular implementation, the memory 104 is a non-volatile memory having a 3D memory array configuration that is monolithically formed in one or more physical levels of arrays of memory cells having an active area disposed above a silicon substrate. Alternatively, the memory 104 may have another configuration, such as a two-dimensional (2D) memory configuration or a non-monolithic 3D memory configuration (e.g., a stacked die 3D memory configuration).

The device 102 may further include a controller 120 coupled to the memory device 103. In some implementations, the controller 120 corresponds to a semiconductor die that includes components of the controller 120. The controller 120 may include an interface 118 (e.g., a memory interface) to the memory device 103 and an interface 150 (e.g., a host interface) to the device 170. The controller 120 may further include a first processing core, such as a first processing core 122 (e.g., a core of a first central processing unit (CPU)). The controller 120 may also include a second processing core, such as a second processing core 138 (e.g., a core of a second CPU).

FIG. 1 also depicts that the controller 120 may include one or more hardware cores, such as a first hardware core 146 and a second hardware core 148. As used herein, “hardware core” may indicate logic circuitry that is configured to perform a set of one or more application-specific tasks (e.g., instead of performing general purpose tasks). An example of hardware core is a core of a digital signal processor (DSP) device, a core of an image processor device, a “peripheral” core, or a core configured to perform a specific task, as illustrative examples. As used herein, “processing core” may indicate a core of a general purpose processor, such as a CPU core (e.g., the processing cores 122, 138). As used herein, “core” may refer to a processing core or a hardware core. To further illustrate, a first core may include either a first processing core (e.g., the first processing core 122) or a first hardware core (e.g., the first hardware core 146), and a second core may include either a second processing core (e.g., the second processing core 138) or a second hardware core (e.g., the second hardware core 148). The cores 122, 138, 146, and 148 may be included in a data path of the controller 120. Two or more cores of the cores 122, 138, 146, and 148 may perform operations concurrently during operation of the device 102.

The controller 120 may further include a master clock device, such as a master clock core 130. The master clock core 130 may be configured to generate a master clock signal 134 (e.g., using an oscillator 132). The master clock core 130 may be configured to provide the master clock signal 134 to one or more of the processing cores 122, 138 and the hardware cores 146, 148 using one or more connections (e.g., one or more buses or other structures), such as a system bus 144. In some implementations, the system bus 144 is configured to operate in accordance with a Joint Test Action Group (JTAG) standard. The master clock core 130 may include or may be coupled to a clock gating circuit 136.

The device 102 and the device 170 may be coupled via a connection, such as a bus, a wireless connection, a network connection, or another connection. The connection may be a bus interface, such as a serial advanced technology attachment (SATA) or peripheral component interface express (PCIe) interface. In one embodiment, the bus interface may be a non-volatile memory express (NVMe) or fiber channel over Ethernet (FCoE) interface. The system 100 may correspond to a solid state drive (SSD), such as found in computing devices, such as laptop computers, and tablet computers. In some implementations, the system 100, the device 102, or the memory 104 may be integrated within a network-accessible data storage system, such as an enterprise data system, a network-attached storage (NAS) system, or a cloud data storage system, as illustrative examples.

During operation, the device 102 may operate according to a test mode of operation or another mode of operation (e.g., a user mode of operation). To illustrate, a test process may be performed after fabrication of a die that includes the controller 120. The test process may include verifying certain operations of one or more components of the controller 120, such as any of the first processing core 122, the second processing core 138, the first hardware core 146, or the second hardware core 148.

During the test process, the device 170 may execute a test program 172 and may issue test commands 174 to the processing cores 122, 138. For example, the test commands 174 may instruct the first processing core 122 to execute a first set of instructions 124 and/or may instruct the second processing core 138 to execute a second set of instructions 140. Any of the sets of instructions 124, 140 may include test code in connection with the test process. For example, the second set of instructions 140 may include test code 141. One or more of the processing cores 122, 138 may be configured to receive the test commands 174 from the device 170 (e.g., during a test process to debug the controller 120). In some cases, one or more of the test commands 174 may comply with a JTAG standard.

The first processing core 122 may include an action point detector 126 configured to detect an action point 128 (e.g., a hardware debug utility). As a non-limiting illustrative example, the action point detector 126 may include a comparator configured to compare a value of program counter of the first processing core 122 to detect whether the value corresponds to the action point 128. The action point 128 may define one or more conditions to be detected by the action point detector 126 and one or more tasks to be performed in response to detecting the one or more conditions. As an illustrative example, the one or more conditions may include a program counter of the first processing core 122 storing a particular value (e.g., reaching a particular instruction address or range of addresses during execution of the first set of instructions 124). The one or more conditions may include reading from or writing to a particular address or range of addresses. Detecting an action point may cause a first processing core to perform one or more tasks. For example, detection of the action point 128 may interrupt the first processing core 122, halt the first processing core 122, cause the first processing core 122 to halt execution of the first set of instructions 124, cause the first processing core 122 to perform one or more other actions, or a combination thereof In this case, the action point 128 may correspond to a breakpoint (e.g., a breakpoint instruction included in the first set of instructions 124) that causes the first core 122 to halt execution of the first set of instructions 124. Alternatively, the first processing core 122 may perform another action in response to detecting the action point 128 (e.g., by continuing to execute the first set of instructions 124 and/or by performing one or more other operations in response to detecting the action point 128).

In response to detecting the action point 128, the action point detector 126 may generate a stall signal 142. In certain devices, the stall signal 142 may correspond to an “internal” signal that is used at the first processing core 122, such as to cause the first processing core 122 to halt execution of the first set of instructions 124. In accordance with the disclosure, the action point detector 126 may be configured to output the stall signal 142 from the first processing core 122. For example, the action point detector 126 may provide the stall signal 142 to the master clock core 130 using the system bus 144.

The master clock core 130 may be configured to clock gate the master clock signal 134 to one or more cores of the controller 120 in response to the stall signal 142. For example, the clock gating circuit 136 may be configured to receive the stall signal 142 from the first processing core 122 via the system bus 144 and to clock gate the master clock signal 134 in response to the stall signal 142. In some implementations, the clock gating circuit 136 may be configured to deactivate (e.g., remove power from) the oscillator 132 to clock gate the master clock signal 134. In other implementations, the oscillator 132 may remain activated after clock gating of the master clock signal 134 (such as if a latch that receives the master clock signal 134 is deactivated in response to the stall signal 142 instead of deactivation of the oscillator 132).

Clock gating the master clock signal 134 to a core may “freeze” the core. For example, clock gating the master clock signal 134 may freeze a state of one or more of the processing cores 122, 138 and/or the hardware cores 146, 148 (e.g., to keep an internal core state intact). For example, in implementations where detection of the action point 128 does not cause the first processing core 122 to halt execution of the first set of instructions 124, then clock gating the master clock signal 134 may cause the first processing core 122 to halt execution of the first set of instructions 124. As another example, clock gating the master clock signal 134 may cause the second processing core 138 to halt execution of the second set of instructions 140. As an additional example, clock gating the master clock signal 134 may cause one or more of the hardware cores 146, 148 to halt operations (e.g., to “freeze” states of the hardware cores 146, 148). “Freezing” one or more of the processing cores 122, 138 and the hardware cores 146, 148 may prevent states of the processing cores 122, 138 and the hardware cores 146, 148 from changing, such as by preventing values of one or more registers of the processing cores 122, 138 from being modified as a result of executing the sets of instructions 124, 140. “Freezing” the processing cores 122, 138 and the hardware cores 146, 148 may improve accuracy and/or efficiency of debugging the controller 120, such as by enabling the test program 172 to access internal states of the processing cores 122, 138 to detect one or more hardware errors and/or software errors associated with the processing cores 122, 138. For example, halting the second processing core 138 in response to the stall signal 142 may enable the test program 172 to detect one or more conditions associated with the second processing core 138 that result in the action point 128 (e.g., concurrent attempts by the processing cores 122, 138 to access a shared resource resulting in a priority conflict, as a non-limiting illustrative example).

In some cases, the test commands 174 may include one or more commands to cause the controller 120 to provide one or more state indications of one or more components of the controller 120. For example, after clock gating the master clock signal 134, the device 170 may send a command to the controller 120 to cause the controller 120 to provide an indication of a state of one or more cores (e.g., one or more of the first processing core 122, the second processing core 138, the first hardware core 146, or the second hardware core 148). To further illustrate, the indication may identify a counter value (e.g., a value of a program counter of a core), a state of a state machine, a state of a logic circuit, a value stored by register of a core, information stored at a register file of a core, data stored at a data cache of a core, instructions stored at an instruction cache of a core, one or more values at an execution unit of a core, one or more values at a pipeline stage of a core, one or more values at an arithmetic and logic unit (ALU) of a core, other information, or a combination thereof The indication may be used by the device 170 in connection with a debugging process to debug the controller 120. In another implementation, the device 102 may include an on-chip debugger (e.g., a debugger integrated within a controller die of the controller 120) that is configured to perform certain debugging operations (e.g., debugging operations associated with the test program 172).

The example of FIG. 1 illustrates that an “internal” signal of a processing core (e.g., the stall signal 142 of the first processing core 122) may be used to clock gate another core (e.g., one or more processing cores and/or one or more hardware cores). For example, the stall signal 142 of the first processing core 122 may be used to cause the second processing core 138 to halt execution of the second set of instructions 140. Halting execution at the second processing core 138 in response to the stall signal 142 may improve accuracy and/or efficiency of certain debugging operations. For example, halting the second processing core 138 in response to the stall signal 142 may enable the test program 172 to detect one or more conditions associated with second processing core 138 that result in the action point 128.

Although certain operations of FIG. 1 have been described with reference to the master clock core 130, it should be appreciated that certain devices may not include a master clock device. As an illustrative example, in some cases, the controller 120 may include multiple asynchronous clock domains that are not controlled by a master clock device. In such implementations, one or more other components of the controller 120 (e.g., the first processing core 122 and/or the second processing core 138) may include circuitry corresponding to the clock gating circuit 136. A first core (e.g., the first processing core 122) may be configured to provide a stall signal (e.g., the stall signal 142) to a second core (e.g., to the second processing core 138 using the system bus 144). The second core may be configured to receive the stall signal 142 from the first processing core 122 and may be configured to receive the stall signal from the first processing core 122 and to halt execution of the second set of instructions 140 in response to receiving the stall signal 142.

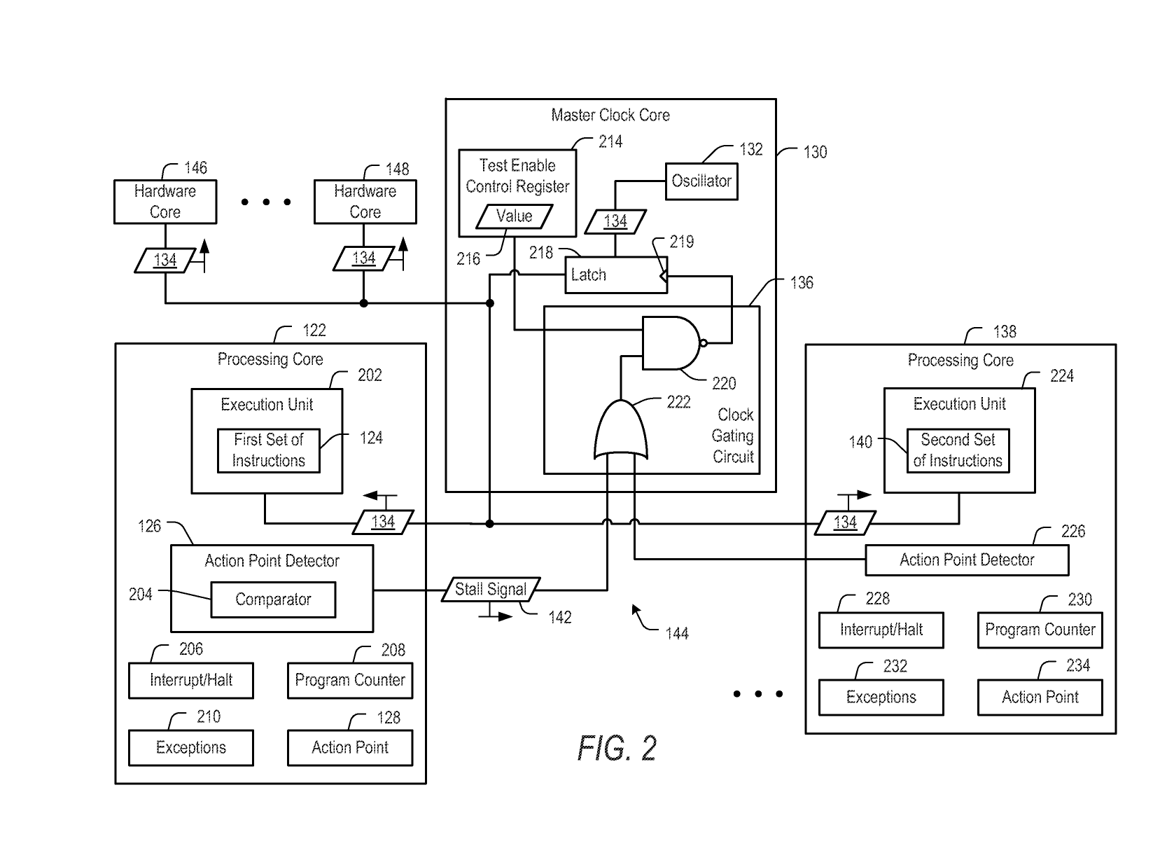

Further, although certain operations have been described with reference to the first processing core 122, another processing core may output one or more stall signals in response to detecting one or more action points (alternatively or in addition to the first processing core 122 outputting the stall signal 142). For example, the second processing core 138 may include an action point detector that may correspond to the action point detector 126, as described further with reference to FIG. 2.

FIG. 2 depicts certain aspects associated with illustrative implementations of the first processing core 122, the master clock core 130, the second processing core 138, and the system bus 144. FIG. 2 also depicts the hardware cores 146, 148.

The first processing core 122 may include an execution unit 202 and a program counter 208. The execution unit 202 may be configured to execute instructions, such as the first set of instructions 124. The execution unit 202 may be responsive to one or more signals, such as the master clock signal 134, one or more external control signals corresponding to interrupts 206, one or more internal control signals corresponding to exceptions 210, or a combination thereof In some cases, an action point (e.g., the action point 128) may correspond to one or more of the interrupts 206 or the exceptions 210. For example, receiving an interrupt or generating an exception may trigger the action point detector 126 to detect an action point, such as the action point 128. Examples of conditions that may result in an exception include a divide-by-zero error, a bus error, or an address violation error.

The second processing core 138 may include an execution unit 224 and a program counter 230. The execution unit 224 may be configured to execute instructions, such as the second set of instructions 140. The execution unit 224 may be responsive to one or more signals, such as the master clock signal 134, one or more external control signals corresponding to interrupts 228, one or more internal control signals corresponding to exceptions 232, or a combination thereof The second processing core 138 may also include an action point detector 226 configured to detect one or more action points (e.g., an action point 234). In some cases, an action point (e.g., the action point 234) may correspond to one or more of the interrupts 228 or the exceptions 232. For example, receiving an interrupt or generating an exception may trigger the action point detector 226 to detect an action point, such as the action point 234.

The master clock core 130 may include the oscillator 132 and the clock gating circuit 136. The oscillator 132 may be coupled to a latch 218. The latch 218 may be coupled to the oscillator 132 and to the clock gating circuit 136. The master clock core 130 may be configured to provide the master clock signal 134 to one or more of the cores 122, 138, 146, and 148 (e.g., using the system bus 144).

The clock gating circuit 136 may include one or more logic circuits, such as a NOT-AND (NAND) gate 220 and an OR gate 222. The OR gate 222 may include a first input coupled to the action point detector 126 and may further include a second input coupled to the action point detector 226. An output of the OR gate 222 may be coupled to the NAND gate 220. The NAND gate 220 may include a first input coupled to a test enable control register 214 and may further include a second input coupled to the OR gate 222. An output of the NAND gate 220 may be coupled to the latch 218 (e.g., to an enable input 219 of the latch 218).

In some implementations, one or more action points (e.g., the action points 128, 234) and one or more exceptions (e.g., the exceptions 210, 232) may be initialized to detect various faults in each processing core (e.g., the processing cores 122, 138) and may be used to activate a global stall signal in response to identifying a fault. The global stall signal may be configured to halt each core of the controller 120 of FIG. 1. A plurality of failure conditions, which may be specific for each processing core, may be developed and executed by each processing core.

During operation, the master clock core may generate the master clock signal 134 using the oscillator 132 and may provide the master clock signal 134 to any of the cores 122, 138, 146, and 148 (e.g., via the system bus 144) to control (e.g., time) operations of any of the cores 122, 138, 146, and 148. For example, the master clock signal 134 may be provided to the execution units 202, 224 during execution of the sets of instructions 124, 140, such as in connection a test process associated with the processing cores 122, 138. During the test process, a value 216 stored at the test enable control register 214 may indicate a test mode of operation. For example, one or more of the test commands 174 of FIG. 1 may set (or cause the controller 120 of FIG. 1 to set) the value 216 to indicate the test mode of operation (e.g., by causing the test enable control register 214 to store a first logic value, such as a high logic value).

The action point detector 126 may detect one or more action points during execution of the first set of instructions 124 by the execution unit 202. For example, the action point detector 126 may detect the action point 128. To illustrate, in some implementations, the action point detector 126 may include a comparator 204. The comparator 204 may be configured to detect whether a value indicated by the program counter 208 corresponds to a value associated with the action point 128. In this example, if the comparator 204 detects that the value indicated by the program counter 208 corresponds to the value associated with the action point 128, the action point detector 126 may output the stall signal 142.

The clock gating circuit 136 may be responsive to the stall signal 142. For example, the stall signal 142 may cause the OR gate 222 to output a signal having a first logic value (e.g., a high logic value). The NAND gate 220 may be responsive to the signal from the OR gate 222. In response to value 216 and the signal from the OR gate 222 having a high logic value, the clock gating circuit 136 may output a signal. For example, the NAND gate 220 may output a signal having a second logic value (e.g., a low logic value).

The clock gating circuit 136 may be configured to clock gate the master clock signal 134 in response to the stall signal 142 from the action point detector 126. For example, the clock gating circuit 136 may provide a low logic value to an enable input of the latch 218, which may cause the latch 218 to cease to provide the master clock signal 134 to the processing cores 122, 138. Alternatively or in addition, in some implementations, the clock gating circuit 136 may be configured to deactivate the oscillator 132 in response to the stall signal 142 (e.g., by removing power from the oscillator 132). Clock gating the master clock signal 134 may cause the processing cores 122, 138 to halt instruction execution (e.g., by “freezing” states of the processing cores 122, 138).

“Freezing” the processing cores 122, 138 may improve accuracy and/or efficiency of a debugging process, such as by enabling access to components of the processing cores 122, 138 (e.g., the program counters 208, 230 and/or one or more other components) to determine internal states of the processing cores 122, 138 (e.g., a program counter value and/or another value). Determining internal states of the processing cores 122, 138 may enable a testing device (e.g., the device 170 of FIG. 1) to detect one or more hardware errors and/or software errors associated with the processing cores 122, 138. For example, halting the second processing core 138 in response to the stall signal 142 may enable the device 170 of FIG. 1 to detect one or more conditions associated with the second processing core 138 that result in detection of a condition associated with the action point 128 (e.g., concurrent attempts by the processing cores 122, 138 to access a shared resource resulting in a priority conflict, as a non-limiting illustrative example). Alternatively or in addition, states of the hardware cores 146, 148 may be accessed after gating the master clock signal 134 (e.g., for use in connection with debugging any of the cores 122, 138, 146, and 148).

Although certain examples described with reference to FIGS. 1 and 2 are described with reference to the first processing core 122 and/or the second processing core 138, it should be appreciated that certain aspects of the disclosure are applicable to one or more other devices. For example, in some circumstances, another processing core (e.g., the second processing core 138, or another processing core of the device 102) may generate a stall signal, such as in response to the action point detector 226 detecting a condition associated with the action point 234. As another example, clock gating the master clock signal 134 may affect one or more other devices alternatively or in addition to the processing cores 122, 138, such as by halting operations at the first hardware core 146, the second hardware core 148, another core, or a combination thereof As an additional example, in some implementations, clock gating circuit 136 may be coupled to a different number of devices as compared to the example of FIG. 2. If the clock gating circuit 136 is coupled to one processing core (e.g., either the first processing core 122 or second processing core 138) instead of multiple processing cores (e.g., the processing cores 122, 138 in the example of FIG. 2), then the OR gate 222 may be omitted from the master clock core 130 (e.g., by directly coupling one of the action point detectors 126, 226 to the NAND gate 220). If the clock gating circuit 136 is coupled to more than two cores (e.g., n cores, where n indicates a positive integer number greater than one), then the OR gate 222 may include n inputs, and each of the n inputs may be coupled to a corresponding one of the n cores. (FIG. 2 illustrates an example where n=2.)

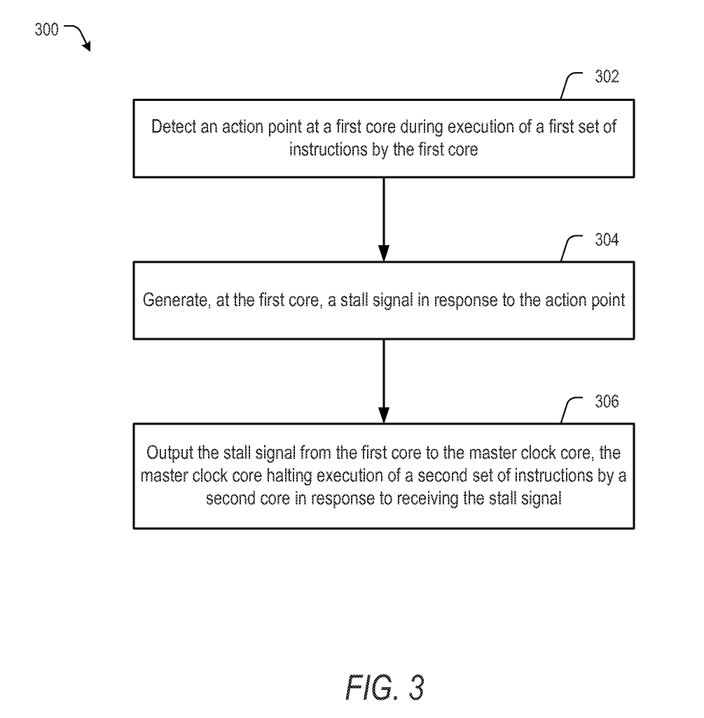

Referring to FIG. 3, an illustrative example of a method is depicted and generally designated 300. The method 300 may be performed in a device (e.g., the device 102) that includes a first core (e.g., the first processing core 122), a second core (e.g., the second processing core 138 or a hardware core, such as one of the hardware cores 146, 148), and a master clock core (e.g., the master clock core 130).

The method 300 includes detecting an action point at the first core during execution of a first set of instructions by the first core, at 302. For example, the action point detector 126 of the first processing core 122 may detect the action point 128 during execution of the first set of instruction 124. In some examples, detecting the action point 128 may include determining (e.g., by the action point detector 126) that the program counter 208 indicates a particular address or range of addresses during execution of the first set of instructions 124.

The method 300 further includes generating, at the first core, a stall signal in response to the action point, at 304. For example, the first processing core 122 may generate the stall signal 142 in response to the action point detector 126 detecting the action point 128.

The method 300 further includes outputting the stall signal from the first core to the master clock core, at 306. The master clock core halts execution of a second set of instructions by a second core in response to receiving the stall signal. For example, the first processing core 122 may output the stall signal 142 to the master clock core 130, which may cause the master clock core 130 to clock gate the master clock signal 134. Clock gating the master clock signal 134 may cause the second processing core 138 to halt execution of the second set of instructions 140 by the second processing core 138 (e.g., by ceasing to provide a master clock signal to the second core in response to the stall signal, such as by ceasing to provide the master clock signal 134 to the second processing core 138 in response to the stall signal 142). In some implementations, the stall signal is provided to the master clock core using a system bus, such as the system bus 144. In an illustrative example, outputting the stall signal from the first core to the master clock core further causes the master clock core to halt operations of one or more hardware cores of the device (e.g., the hardware cores 146, 148 of the device 102).

The method 300 may enable a test process at a device. For example, one or more of the first set of instructions or the second set of instructions may include test code associated with a debugging process (e.g., a debugging process performed by the device 170 to debug the device 102 or the controller 120).

In some implementations, a computer-readable medium stores instructions executable by a first processing core to perform operations. For example, the computer-readable medium may correspond to the memory 104, the instructions may correspond to the first set of instructions 124, and the first processing core may correspond to the first processing core 122. The operations include detecting an action point (e.g., the action point 128) during execution of the instructions by the first processing core. The operations further include generating a stall signal (e.g., the stall signal 142) in response to detecting the action point and outputting the stall signal to a master clock core (e.g., the master clock core 130) to cause the master clock core to clock gate a second processing core (e.g., the second processing core 138). In some implementations, detecting the action point includes detecting a particular value (e.g., a particular instruction address or range of addresses) indicated by a program counter (e.g., the program counter 208) of the first processing core.

Although various components depicted herein are illustrated as block components and described in general terms, such components may include one or more microprocessors, state machines, or other circuits configured to enable such components to perform one or more operations described herein. For example, the action point detectors 126, 226 may represent physical components, such as hardware controllers, state machines, logic circuits, or other structures, to enable the processing cores 122, 138 to detect action points, such as the action points 128, 234. To further illustrate, FIG. 2 depicts that the action point detector 126 may include the comparator 204. As another example, FIG. 2 depicts that the clock gating circuit 136 may include one or more logic circuits, such as the OR gate 222 and the NAND gate 220.

Alternatively or in addition, one or more components described herein may be implemented using a microprocessor or microcontroller programmed to perform operations, such as one or more operations of the method 300 of FIG. 3. Instructions executed by the controller 120 and/or the device 170 may be retrieved from the memory 104 or from a separate memory location that is not part of the memory 104, such as from a read-only memory (ROM).

The device 102 may be coupled to, attached to, or embedded within one or more accessing devices, such as within a housing of the device 170. For example, the device 102 may be embedded within the device 170 in accordance with a Joint Electron Devices Engineering Council (JEDEC) Solid State Technology Association Universal Flash Storage (UFS) configuration. To further illustrate, the device 102 may be integrated within an electronic device (e.g., the device 170), such as a mobile telephone, a computer (e.g., a laptop, a tablet, or a notebook computer), a music player, a video player, a gaming device or console, a component of a vehicle (e.g., a vehicle console), an electronic book reader, a personal digital assistant (PDA), a portable navigation device, or other device that uses internal non-volatile memory.

In one or more other implementations, the device 102 may be implemented in a portable device configured to be selectively coupled to one or more external devices, such as a host device. For example, the device 102 may be removable from the device 170 (i.e., “removably” coupled to the device 170). As an example, the device 102 may be removably coupled to the device 170 in accordance with a removable universal serial bus (USB) configuration.

The device 170 may correspond to a mobile telephone, a computer (e.g., a laptop, a tablet, or a notebook computer), a music player, a video player, a gaming device or console, a component of a vehicle (e.g., a vehicle console), an electronic book reader, a personal digital assistant (PDA), a portable navigation device, another electronic device, or a combination thereof The device 170 may communicate via a controller, which may enable the device 170 to communicate with the device 102. The device 170 may operate in compliance with a JEDEC Solid State Technology Association industry specification, such as an embedded MultiMedia Card (eMMC) specification or a Universal Flash Storage (UFS) Host Controller Interface specification. In these examples, the test commands 174 may comply with a JEDEC specification, such as an eMMC specification of a UFS specification. The device 170 may operate in compliance with one or more other specifications, such as a Secure Digital (SD) Host Controller specification as an illustrative example. In this example, the test commands 174 may comply with an SD specification. Alternatively, the device 170 may communicate with the device 102 in accordance with another communication protocol.

In some implementations, the system 100, the device 102, or the memory 104 may be integrated within a network-accessible data storage system, such as an enterprise data system, an NAS system, or a cloud data storage system, as illustrative examples. In these examples, the test commands 174 may comply with a network protocol, such as an Ethernet protocol, a local area network (LAN) protocol, or an Internet protocol, as illustrative examples.

In some implementations, the device 102 may include a solid state drive (SSD). The device 102 may function as an embedded storage drive (e.g., an embedded SSD drive of a mobile device), an enterprise storage drive (ESD), a cloud storage device, a network-attached storage (NAS) device, or a client storage device, as illustrative, non-limiting examples. In some implementations, the device 102 may be coupled to the device 170 via a network. For example, the network may include a data center storage system network, an enterprise storage system network, a storage area network, a cloud storage network, a local area network (LAN), a wide area network (WAN), the Internet, and/or another network.

To further illustrate, the device 102 may be configured to be coupled to the device 170 as embedded memory, such as in connection with an embedded MultiMedia Card (eMMC®) (trademark of JEDEC Solid State Technology Association, Arlington, Virginia) configuration, as an illustrative example. The device 102 may correspond to an eMMC device. As another example, the device 102 may correspond to a memory card, such as a Secure Digital (SD®) card, a microSD® card, a miniSD™ card (trademarks of SD-3C LLC, Wilmington, Del.), a MultiMediaCard™ (MMC™) card (trademark of JEDEC Solid State Technology Association, Arlington, Va.), or a CompactFlash® (CF) card (trademark of SanDisk Corporation, Milpitas, Calif.). The device 102 may operate in compliance with a JEDEC industry specification. For example, the device 102 may operate in compliance with a JEDEC eMMC specification, a JEDEC Universal Flash Storage (UFS) specification, one or more other specifications, or a combination thereof.

The memory 104 may include a resistive random access memory (ReRAM), a flash memory (e.g., a NAND memory, a NOR memory, a single-level cell (SLC) flash memory, a multi-level cell (MLC) flash memory, a divided bit-line NOR (DINOR) memory, an AND memory, a high capacitive coupling ratio (HiCR) device, an asymmetrical contactless transistor (ACT) device, or another flash memory), an erasable programmable read-only memory (EPROM), an electrically-erasable programmable read-only memory (EEPROM), a read-only memory (ROM), a one-time programmable memory (OTP), another type of memory, or a combination thereof In a particular embodiment, the device 102 is indirectly coupled to an accessing device (e.g., the device 170) via a network. For example, the device 102 may be a network-attached storage (NAS) device or a component (e.g., a solid-state drive (SSD) component) of a data center storage system, an enterprise storage system, or a storage area network. The memory 104 may include a semiconductor memory device.

Semiconductor memory devices include volatile memory devices, such as dynamic random access memory (“DRAM”) or static random access memory (“SRAM”) devices, non-volatile memory devices, such as resistive random access memory (“ReRAM”), magnetoresistive random access memory (“MRAM”), electrically erasable programmable read only memory (“EEPROM”), flash memory (which can also be considered a subset of EEPROM), ferroelectric random access memory (“FRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure. In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate). As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Alternatively, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this disclosure is not limited to the two dimensional and three dimensional exemplary structures described but cover all relevant memory structures within the spirit and scope of the disclosure as described herein and as understood by one of skill in the art. The illustrations of the embodiments described herein are intended to provide a general understanding of the various embodiments. Other embodiments may be utilized and derived from the disclosure, such that structural and logical substitutions and changes may be made without departing from the scope of the disclosure. This disclosure is intended to cover any and all subsequent adaptations or variations of various embodiments. Those of skill in the art will recognize that such modifications are within the scope of the present disclosure.

The above-disclosed subject matter is to be considered illustrative, and not restrictive, and the appended claims are intended to cover all such modifications, enhancements, and other embodiments, that fall within the scope of the present disclosure. Thus, to the maximum extent allowed by law, the scope of the present invention is to be determined by the broadest permissible interpretation of the following claims and their equivalents, and shall not be restricted or limited by the foregoing detailed description.

What is claimed is:

1. An apparatus comprising:
a first core, the first core including an action point detector;
a master clock core coupled to the first core, the master clock core configured to generate a master clock signal; and
a clock gating circuit configured to clock gate the master clock signal in response to a stall signal from the action point detector.

2. The apparatus of claim 1, further comprising a second core coupled to the master clock core and configured to receive the master clock signal from the master clock core, wherein the clock gating circuit is further configured to gate the master clock signal to the second core in response to the stall signal.

3. The apparatus of claim 1, wherein the clock gating circuit includes a logic circuit having a first input that is responsive to the stall signal and a second input configured to receive a test mode enable signal from a testing device during a test process.

4. The apparatus of claim 3, wherein the logic circuit includes a NOT-AND (NAND) gate.

5. The apparatus of claim 3, further comprising a latch coupled to the clock gating circuit, the latch including an enable input coupled to an output of the clock gating circuit.

6. The apparatus of claim 1, further comprising a system bus coupled to the first core and to the master clock core.

7. The apparatus of claim 6, wherein the first core is configured to provide the stall signal to the master clock core using the system bus.

8. The apparatus of claim 1, further comprising a data storage device including a controller that includes the first core and the master clock core, the data storage device further include a non-volatile memory coupled to the controller.

9. A method comprising:
in a device that includes a first core, a second core, and a master clock core, performing:
detecting an action point at the first core during execution of a first set of instructions by the first core;
generating, at the first core, a stall signal in response to the action point; and
outputting the stall signal from the first core to the master clock core, the master clock core halting execution of a second set of instructions by a second core in response to receiving the stall signal.

10. The method of claim 9, wherein the stall signal is provided to the master clock core using a system bus.

11. The method of claim 9, wherein detecting the action point includes determining that a program counter of the first core indicates a particular address or range of addresses during execution of the first set of instructions.

12. The method of claim 9, wherein causing the second core to halt execution of the second set of instructions includes ceasing to provide a master clock signal to the second core in response to the stall signal.

13. The method of claim 9, wherein the first set of instructions includes test code associated with a debugging process.

14. The method of claim 9, wherein the first core includes a first central processing unit (CPU), and wherein the second core includes a second CPU.

15. The method of claim 9, wherein the first core includes a first central processing unit (CPU), and wherein the second core includes a hardware core.

16. The method of claim 9, wherein outputting the stall signal from the first core to the master clock core further causes the master clock core to halt operations of one or more hardware cores of the device.

17. An apparatus comprising:
a first core configured to generate a stall signal in response to detecting an action point during execution of a first set of instructions; and
a second core, wherein the second core is coupled to the first core, the second core configured to receive the stall signal from the first core and to halt execution of a second set of instructions in response to receiving the stall signal.

18. The apparatus of claim 17, further comprising a system bus coupled to the first core and to the second core, the first core configured to provide the stall signal via the system bus to the second core.

19. The apparatus of claim 17, wherein the first set of instructions includes test code associated with a debugging process.

20. A computer-readable medium storing instructions executable by a first processing core to perform operations comprising:
detecting an action point during execution of the instructions by the first processing core;
generating a stall signal in response to detecting the action point; and
outputting the stall signal to a master clock core to cause the master clock core to clock gate a second processing core.

21. The computer-readable medium of claim 20, wherein detecting the action point includes detecting a particular value indicated by a program counter of the first processing core.
